(19) United States
(12) Patent Application Publication
(10) Pub. No.: US 2026/0282803 A1
(43) Pub. Date: Sep. 17, 2026

(54) PEDESTAL STEM COOLING SYSTEM

(71) Applicant: Lam Research Corporation, Fremont, CA (US)

(72) Inventors: Jacob Lee Hiester, Newberg, OR (US); Bryan Anthony Cmelak, King City, OR (US); Patrick Girard Breiling, Tigard, OR (US); Christopher Gage, Truckee, CA (US)

(21) Appl. No.: 19/480,261

(22) PCT Filed: May 2, 2024
(86) PCT No.: PCT/US2024/027568

§ 371 Date: Oct. 30, 2025

Related U.S. Application Data
(60) Provisional application No. 63/500,484, filed on May 5, 2023.

(51) Int. Cl. H10P 72/00; H10P 72/76

(52) U.S. Cl. CPC H10P 72/0434; H10P 72/7616; H10P 72/7618; H10P 72/7626

(57) ABSTRACT

Pedestal stem cooling systems for providing effective cooling to pedestal stems in situations in which the pedestals may be at temperatures exceeding 600° C. are provided. The system comprises: a pedestal having a first side configured to support a semiconductor wafer during semiconductor processing operations and a second side opposite the first side; a stem having a first end connected with the pedestal and a second end located farther from the second side than the first end of the stem; a support structure connected with the second end of the stem, the support structure having at least one first surface that is axially mated with a second surface located at or proximate to the second end of the stem; and a first cooling passage segment positioned such that at least one first surface is interposed between the first cooling passage segment and the stem.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor manufacturing processes often occur within a chamber in which a semiconductor wafer or semiconductor wafers are supported on pedestals during wafer processing operations. Such a pedestal may be positioned underneath a corresponding gas distribution system, e.g., a showerhead, that may be used to distribute process gases across the exposed side of a semiconductor wafer supported by the pedestal. Pedestals are usually relatively large platform-like structures that are sized larger than the wafers that they are designed to support. Pedestals may include various systems that may be used during various stages of semiconductor wafer processing and/or handling. For example, pedestals may include heaters, cooling systems, chucks (vacuum and/or electrostatic) for clamping a wafer in place, lift pin holes through which lift pins may be extended in order to lift a wafer off of the top surface of the pedestal, electrodes for providing radio-frequency energy that may be used to generate a plasma within the processing chamber, temperature sensors, etc.

Pedestals are typically supported within a semiconductor processing chamber via a stem, which is generally a smaller, column-like structure that extends outward from the underside of the pedestal. In some examples, the stem may extend vertically downward and pass through an aperture in a bottom wall of the processing chamber. In other instances, the stem may extend vertically downward for some distance and then extend radially outward so as to be able to pass through an aperture in a side wall of the processing chamber.

Pedestals are often designed to be movable along a vertical axis, e.g., to allow the pedestal to be moved between different elevations within the processing chamber. For example, the stem that supports a pedestal within a processing chamber may be mounted to a linear actuator or other vertical lift mechanism that may be actuated to cause the stem and pedestal to move vertically. This allows, for example, the distance between the showerhead and the wafer supported by the pedestal to be adjusted or for the wafer to be caused to rest on lift pins while the pedestal is lowered relative to the wafer, thereby providing a gap underneath the wafer into which an end effector may be inserted and then moved upward to lift the wafer off of the lift pins and remove it from the processing chamber.

Discussed herein are systems for more efficiently removing heat that may be generated within, or conducted into, the pedestal and/or stem.

### SUMMARY

Details of one or more implementations of the subject matter described in this specification are set forth in the accompanying drawings and the description below. Other features, aspects, and advantages will become apparent from the description, the drawings, and the claims.

In some implementations, a system may be provided that includes a pedestal having a first side configured to support a semiconductor wafer during semiconductor processing operations and a second side opposite the first side. The system may further include a stem having a first end connected with the pedestal and a second end located farther from the second side than the first end of the stem. The system may also include a support structure connected with the second end of the stem, the support structure having at least one first surface that is axially mated with a second surface located at or proximate to the second end of the stem, and a first cooling passage segment positioned such that the at least one first surface is interposed between the first cooling passage segment and the stem.

In some implementations, at least one of the at least one first surface and the second surface may include a seal groove and the system may further include a seal positioned within the seal groove and compressed between the at least one first surface and the second surface.

In some implementations, the support structure may include a seal collar connected with a bellow seal, the bellow seal may encircle at least part of the stem, and the bellow seal may be made of metal.

In some such implementations, the support structure may further include a polymeric layer interposed between at least a portion of the seal collar and the first cooling passage segment. In such implementations, the support structure may also include a retention collar having a first portion abutting the second end of the stem and a second portion connected with the first portion. The first cooling passage segment may be positioned between the second portion of the retention collar and the second surface of the stem.

In some implementations, the first cooling passage segment may be a tube that extends around the first portion of the retention collar, and the support structure may be configured such that the first portion of the retention collar is compressed against the second end of the stem and at least a portion of the polymeric layer adjacent to the seal collar is in a state of compression.

In some implementations, the polymeric layer may have a first side facing the stem and a second side facing an opposite direction from the first side. The polymeric layer may also be sized such that when the polymeric layer is in an uncompressed state and the first side of the polymeric layer and the second side of the polymeric layer are both in contact with other portions of the support structure, the first portion of the retention collar is not in contact with the second end of the stem.

In some implementations, the at least one first surface of the support structure and the second surface of the stem may define a contact region where the at least one first surface and the second surface overlap one another when viewed along a center axis of the stem extending between the first end of the stem and the second end of the stem. In such implementations, the first cooling passage segment may lie at least partially within a reference volume bounded by interior and exterior edges of the contact region and extending along the center axis of the stem.

In some implementations having the tube, the tube may follow a path around the first portion of the retention collar, the second portion of the retention collar may have a first recessed region extending around the first portion of the retention collar, and the tube may be positioned within, and in contact with, the first recessed region.

In some such implementations, the support structure may further include a load distributor that is at least partially interposed between the first cooling passage segment and the polymeric layer. The load distributor may also be at least partially interposed between the second portion of the retention collar and the polymeric layer. In such implementations, the cooling passage segment may be interposed between at least a portion of the second portion of the retention collar and a portion of the load distributor.

In some such implementations, the load distributor may have an opening through which the first portion of the retention collar extends, the load distributor may have a second recessed region extending around the opening, and the tube may be positioned within, and in contact with, the second recessed region.

In some implementations, the path may be an arcuate path.

In some implementations, a gap may exist between the load distributor and the second portion of the retention collar when the first cooling passage segment is at least touching, but not compressed between, both the load distributor and the retention collar.

In some implementations, the second end of the stem may have a first interior perimeter having a plurality of first lobes extending radially inward from outermost portions of the first interior perimeter.

In some such implementations, the retention collar may have a second interior perimeter having a plurality of second lobes extending radially inward from outermost portions of the second interior perimeter, and the first lobes and the second lobes may be rotationally aligned with each other.

In some implementations, the system may further include a plurality of first threaded fasteners, each first threaded fastener passing through a corresponding through-hole in one of the second lobes and threaded into a corresponding threaded hole in one of the first lobes.

In some implementations, the first lobes may terminate at the second surface and the second lobes may terminate coplanar with the at least one first surface.

In some implementations, the system may further include a plurality of elongate structures extending from the second side of the pedestal and through the stem. Each elongate structure may have a portion that is positioned in between two of the first lobes that are adjacent to one another.

In some implementations, the plurality of elongate structures may include at least a coolant supply passage and a coolant return passage.

In some implementations, the plurality of elongate structures may include at least a first electrical conductor and a second electrical conductor.

In some implementations, the system may further include a central elongate structure extending from the second side of the pedestal and through a center of the stem.

In some implementations, the central elongate structure may be a sensor cable.

In some implementations, the system may further include a second cooling passage segment and a third cooling passage segment, and the first cooling passage segment may be fluidically interposed between the second cooling passage segment and the third cooling passage segment. The first cooling passage segment, the second cooling passage segment, and the third cooling passage segment may be connected together, the second cooling passage segment and the third cooling passage segment may each have a respective portion that is fixed in space relative to a first portion of the support structure, and the retention collar may be connected with one or more other components of the support structure such that the retention collar is removable from a remainder of the support structure without requiring that the respective portions of the second cooling passage segment and the third cooling passage segment moved relative to the first portion of the support structure.

In some implementations, the retention collar may include two halves.

In some implementations, the support structure further may include a support collar that is interposed between a portion of the seal collar and a portion of the retention collar, the support collar having a plurality of mounting features positioned about an outer perimeter thereof.

In some implementations, the system may further include a processing chamber and a showerhead. The pedestal may be located within an interior volume of the processing chamber and the first end of the stem may be located within the interior volume of the processing chamber and the second end of the stem may be located outside of the processing chamber.

In some implementations, the system may further include a hexapod mechanism with a stationary base, a movable base, and six linear actuators. The support structure may be mounted to the movable base, the stationary base may be mounted to the processing chamber, a first end of each linear actuator may be connected with the stationary base, and a second end of each linear actuator may be connected with the movable base.

In some implementations, the system may further include a vertical lift mechanism having a base portion and a movable portion. The support structure may be fixed in space with respect to the movable portion and the vertical lift mechanism may include one or more actuators configured to cause the movable portion to move relative to the base portion responsive to one or more input signals.

### BRIEF DESCRIPTION OF THE DRAWINGS

Reference to the following Figures is made in the discussion below; the Figures are not intended to be limiting in scope and are simply provided to facilitate the discussion below.

FIG. 1 depicts a perspective view of an example apparatus that includes a pedestal, a stem, and a support structure.

FIG. 2 depicts the same example apparatus but with various components thereof shown in exploded view.

FIG. 3 depicts a cross-sectional view of the apparatus of FIG. 1.

FIG. 4 depicts a detail view of the circled region of FIG. 3.

FIG. 5 shows the same cross-sectional detail view as FIG. 4 but with the stem partially withdrawn from the support structure.

FIG. 6 depicts an exploded perspective view of the support structure.

FIGS. 7 and 8 depict top and perspective views of the example retention collar shown in earlier Figures.

FIGS. 9 and 10 depict perspective and top views of an alternate retention collar in which the retention collar is a split or two-part retention collar.

FIGS. 11 and 12 depict perspective cutaway exploded views of the support structure and the second end of the stem.

FIG. 13 depicts a cross-section of an alternate design for a support structure.

FIG. 14 depicts a cross-section of another alternate design for a support structure.

FIG. 15 depicts one example of a semiconductor processing system in which semiconductor processes may be performed using the pedestal cooling systems discussed herein.

FIG. 16 depicts an alternate example semiconductor processing system that is similar to that depicted in FIG. 15 a different pedestal movement mechanism is used.

The above-described Figures are provided to facilitate understanding of the concepts discussed in this disclosure, and are intended to be illustrative of some implementations that fall within the scope of this disclosure, but are not intended to be limiting-implementations consistent with this disclosure and which are not depicted in the Figures are still considered to be within the scope of this disclosure.

### DETAILED DESCRIPTION

As discussed above, semiconductor wafer processing operations are often performed on semiconductor wafers while such wafers are supported within a processing chamber on a pedestal, e.g., a structure typically designed to support a semiconductor wafer from below. Pedestals, in turn, are often supported within the processing chamber by a stem, which are generally much smaller in minimum external cross-sectional size than the pedestals that they support, e.g., on the order of three or four inches in cross-sectional width (as compared with the maximum cross-sectional width of the pedestals, which is typically on the order of twelve inches or more).

Stems are typically hollow in order to allow for electrical power cables (e.g., to power RF electrodes located in the pedestal), coolant supply/return passages (e.g., to provide coolant to, or receive coolant from, cooling passages within the pedestal), or other elongate structures extending from the bottom side of the pedestal to be shielded from the ambient environment within the processing chamber and routed to a location that is external to the processing chamber.

Due to the relatively small cross-sectional area of stems compared to the cross-sectional area of the pedestals they support (with the cross-sectional areas generally being evaluated in horizontal planes intersecting such structures, e.g., planes that are perpendicular to a nominal center axis of the pedestal and stem), it is not uncommon for stems to be subject to high heat loads. For example, if heat is imparted to a pedestal via active heating of the pedestal using heating elements embedded within the pedestal or via process-originating heating, e.g., due to radiative heating from a plasma generated within the processing chamber or via radiative heating from other components within the processing chamber, e.g., such as the showerhead, the stem (and the components routed through it) will generally be the only effective conductive heat transfer path (other than coolant circulated through passages in the pedestal if the pedestal is actively cooled) that is available to evacuate heat from the pedestal. In implementations in which a pedestal is actively cooled, of course, much of the heat from the pedestal may be conveyed out of the pedestal via the coolant that may be flowed through the pedestal and then out of the processing chamber via the stem. However, there may still be significant amounts of heat are conducted through the stem. For example, in an actively cooled pedestal that is heated to 600° C. to 700° C., the stem may easily reach temperatures exceeding 300° C. at the base of the stem. This can be problematic, as the base of the stem is often interfaced with one or more elastomeric seals that prevent atmospheric air from being drawn into the processing chamber via the stem. Such high temperatures may cause such seals to degrade or fail.

Disclosed herein are new designs for stem cooling systems that have high cooling efficiency, thereby correspondingly allowing pedestal temperatures to reach higher values while maintaining temperatures at the base of the stem supporting the pedestal at a level that is below a particular threshold, e.g., the maximum temperature that a seal between the base of the stem and another component may be exposed to without risking degradation or failure of the seal. For example, such cooling systems may allow a pedestal to be kept at 600° C. to 700° C. for extended periods of time while maintaining the temperature at the base of the stem at 250° C. or less.

The stem for a pedestal may generally have a first end that is coupled to the pedestal and a second end that is coupled with a support structure of some sort. In many instances, such support structures may be in some way be interfaced with a bellow seal or other flexible seal structure. The bellow seal or other flexible seal structure may be interfaced at an opposing end with the processing chamber. The bellow seal or other flexible seal structure may thus provide a flexible barrier between the atmosphere within the processing chamber and the atmosphere of the ambient environment, e.g., the ambient environment of a semiconductor fabrication facility in which the tool having the processing chamber is installed. The flexible nature of the bellow seal or other flexible seal structure allows the support structure, as well as the pedestal and stem supported thereby, to move relative to the processing chamber without there being any breach of the pressure environment of the processing chamber.

In instances in which a bellow seal is used, such seals are typically made of stainless steel, as bellow seals made of polymeric materials are prone to collapse, particulate generation, outgassing, and chemical and thermal attack. Bellow seals of other metals are typically not feasible due to fatigue and/or corrosion issues with such materials. Bellow seals made of stainless steels (or other, similar materials) may provide good resistance against corrosion and thermal attack, high fatigue life, and high strength. Such bellow seals are typically welded to stainless steel bases/end flanges that may serve as attachment points for mounting the bellow seal to the processing chamber and/or support structure. However, such stainless steel components typically have a much lower thermal conductivity as compared with the thermal conductivity of the stem. For example, a typical stem may be made of aluminum alloy and may have a thermal conductivity of ~180 W/m-K, whereas stainless steels have among the lowest thermal conductivities of any metal, e.g., ~15 W/m-K. There is thus often a drastic drop in heat transfer across the interface between a stem and such support structures.

In the implementations disclosed herein, various features may be utilized, in isolation or in combination, to still provide a high rate of heat transfer from the stem, into or through the support structure, and into a cooling passage that is integral with or assembled into the support structure. Such implementations may even provide such performance when stainless steel components are in the heat transfer path. Various illustrative examples of such systems are discussed below with respect to the Figures.

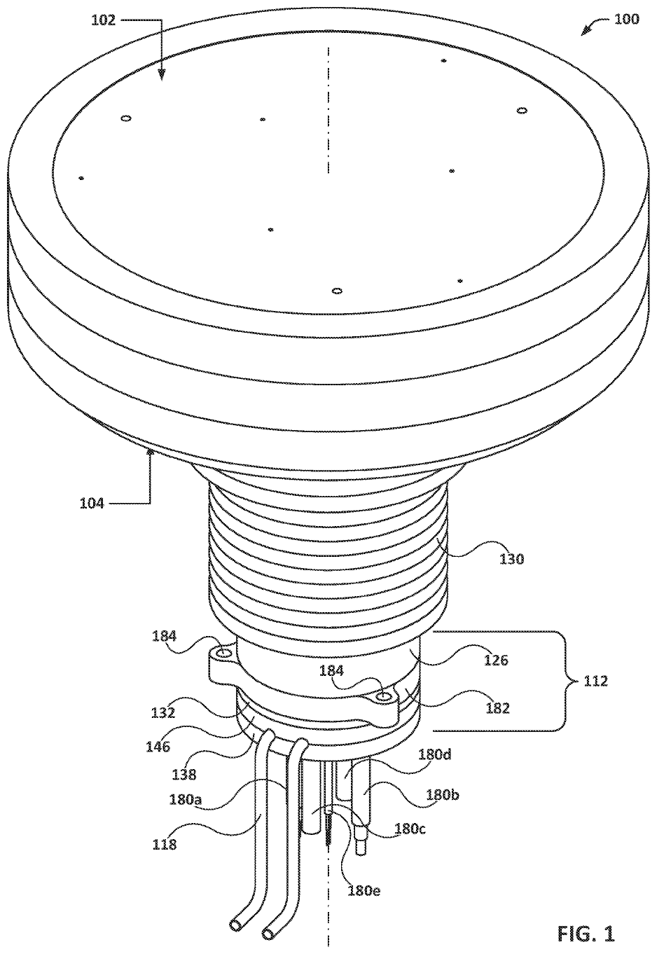

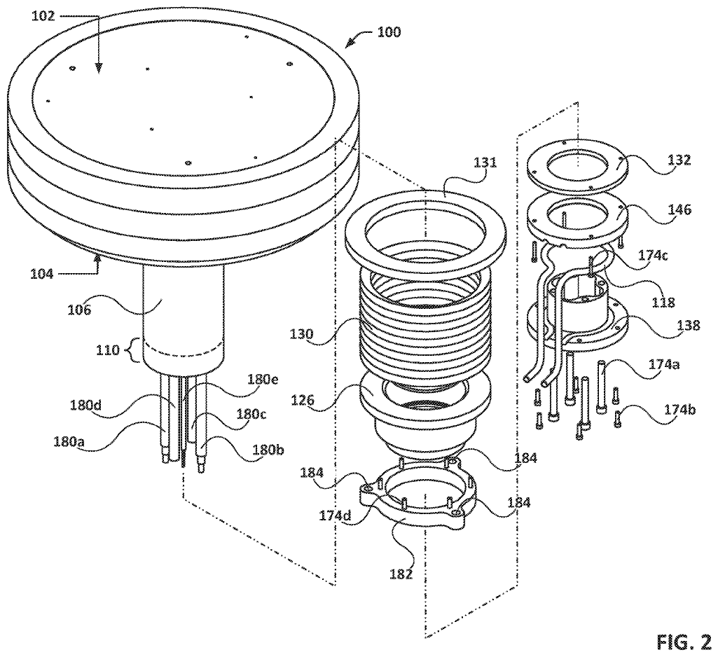

FIG. 1 depicts a perspective view of an example apparatus that includes a pedestal, a stem, and a support structure. FIG. 2 depicts the same example apparatus but with various components thereof shown in exploded view. As can be seen in FIGS. 1 and 2, a pedestal 100 having a first side 102 and a second side 104, opposite the first side 102, is shown. The first side 102 of the pedestal 100 may be configured to support a semiconductor wafer (not shown) during semiconductor processing operations. The pedestal may, for example, be made from any of a variety of materials that are suitable for use in the chemical and thermal environments experienced during the semiconductor processing. For example, the pedestal may be made, in part or in whole, of one or more aluminum alloys, steel alloys (such as stainless steel), ceramics (such as aluminum oxide or aluminum nitride), etc. The pedestal 100 may, in some cases, have one or more features within it that may provide additional functionality to the pedestal during various stages of semiconductor fabrication. For example, the pedestal 100 may include a heating system, a cooling system, an RF electrode, etc., which may be used to add/remove heat and/or provide electrical power that may be used to generate a plasma within the processing chamber.

A stem 106 (see FIG. 2; in FIG. 1, the stem 106 is hidden within bellow seal 130) may be connected with the pedestal 100 and may support the pedestal 100 within a processing chamber. The stem 106, for example, may have a first end (not visible) that is connected with the second side 104 of the pedestal 100 and a second end 110 that is further from the first side 102 and the second side 104 than the first end 108 and connects with the support structure 112. As shown, the stem 106 has an exterior profile that is generally axially symmetric about a center axis of the stem 106, although other implementations may feature a stem 106 that is not axially symmetric, e.g., a radially symmetric stem 106 or even a stem 106 that is bilaterally symmetric or that does not have any symmetry at all. Generally speaking, however, the stem 106 will, as noted earlier, be much smaller in minimum external cross-sectional dimension (taken in cross-sectional planes transverse to the centerline(s) of the stem 106) than the maximum external cross-sectional dimension of the pedestal 100. For example, the stem 106 may have a minimum external cross-sectional dimension that is less than 50% of the maximum cross-sectional dimension of the pedestal 100.

The support structure 112 may, for example, be a multi-component assembly. In this example, the support structure 112 includes a seal collar 126, a support collar 182, a polymeric layer 132, a load distributor 146, and a retention collar 138. However, it will be apparent that other implementations may feature a support structure 112 having more or fewer such major components.

The support structure 112 may generally have an opening that extends through the middle of the support structure 112, e.g., through which cables, coolant flow paths, and other components may traverse to enter or exit from the stem 106. The apparatus may also have a cooling passage 118 that may be positioned so as to be at least partially within the support structure 112 or that may be integral in one of the components that forms the support structure 112. The cooling passage 118 may, for example, extend around most or all of the opening in the support structure.

In this example, the apparatus may include a bellow seal 130 that is connected, e.g., welded, to seal collar 126 at one end and connected to a mounting flange 131 (or other similar structure). The bellow seal 130, the seal collar 126, and the mounting flange 131 are, in this example, made of metal, e.g., a stainless steel alloy. The mounting flange 131, for example, may be mated to a portion of the processing chamber in order to secure one end of the bellow seal 130 in place relative to the processing chamber. The bellow seal 130 may be sized such that the stem 106 is able to extend through the center of the bellow seal 130, i.e., the bellow seal 130 encircles at least part of the stem 106.

In some implementations, the support collar 182 may, as shown, have a plurality of mounting features 184 located about its periphery. In this example, the support collar 182 is a circular ring with a plurality of protrusions extending radially outward therefrom, each protrusion having a mounting feature 184 extending therethrough. Such an implementation may also have a circular opening in the middle that may have a diameter that is the same as or slightly larger than an outer diameter of the seal collar 126 in a region of the seal collar 126 that aligns with the support collar 182 when the support structure 112 is assembled. Such an implementation may allow for the pedestal 100 to be rotated about its center axis relative to the support collar 182, thereby allowing the azimuthal orientation of the pedestal 100 relative to a processing chamber in which the pedestal 100 is installed to be fine-tuned after the support structure 112 and pedestal 100 are installed in the tool having the processing chamber.

However, it will be understood that in other implementations, the mounting features 184 may be connected with other components of the support structure 112, e.g., the mounting features 184 may be integral with the seal collar 126 in some implementations. In such implementations, there may be no separate support collar 182.

The apparatus may also include a retention collar 138 that may be rigidly connected with the stem 106, e.g., via a plurality of threaded fasteners 174a. The retention collar 138 may, for example, have a first portion that may extend through openings in the polymeric layer 132 and the load distributor 146 and butt up against the second end 110 of the stem 106.

The polymeric layer 132 may be used, in effect, as a spring that may be used—in implementations in which the cooling passage 118 is a discrete component separate from, but integrated into, the support structure 112—to compress the cooling passage 118 against other features of the support structure 112 to ensure good thermally conductive contact between the cooling passage 118 and one or more elements of the support structure 112. The polymeric layer 132 may also be used to provide a compliant gap-filler that may assist with providing a desired degree of clamping force to the stem 106, as will be discussed later with respect to other Figures.

The load distributor 146, if used, may be arranged to exert a compressive load on, for example, the polymeric layer 132. The load distributor 146 may, for example, have an overall shape that is similar to that of the polymeric layer 132. The load distributor 146 may, in some implementations (such as the one depicted), be connected with the seal collar 126 by a plurality of threaded fasteners 174c. The polymeric layer 132 may, if present, be interposed between the load distributor 146 and the seal collar 126. In at least some such implementations, remaining portions of the support structure 112 may be able to be removed from the support structure 112, leaving at least the polymeric layer 132, the seal collar 126, and the load distributor 146 in place. It will be understood that the term “interposed,” as used in the context of “part A is interposed between parts B and C,” refers to an arrangement in which part A is positioned between part B and part C, but not necessarily directly between parts B and C. For example, the fact that a part D may also be in between parts B and C and also in between parts A and B would not be viewed as causing part A to no longer be interposed between parts B and C.

The retention collar 138, as shown, may be configured to be rigidly connected with the stem 106 and may, in concert with other components of the support structure 112, act to retain the stem 106 in place relative to the support structure 112. In the depicted example, the retention collar 138 has two main portions—a central, cylindrical first portion that may extend upwards through openings in the centers of the load distributor 146, the polymeric layer 132, and the seal collar 126 and that may then butt against the second end 110 of the stem 106, and a second portion that extends radially outward from the first portion. The second portion may, for example, act as a flange that may exert compressive force on the polymeric layer 132, the load distributor 146, and the segment of the cooling passage 118 that is interposed between the stem 106 and the second portion of the retention collar 138.

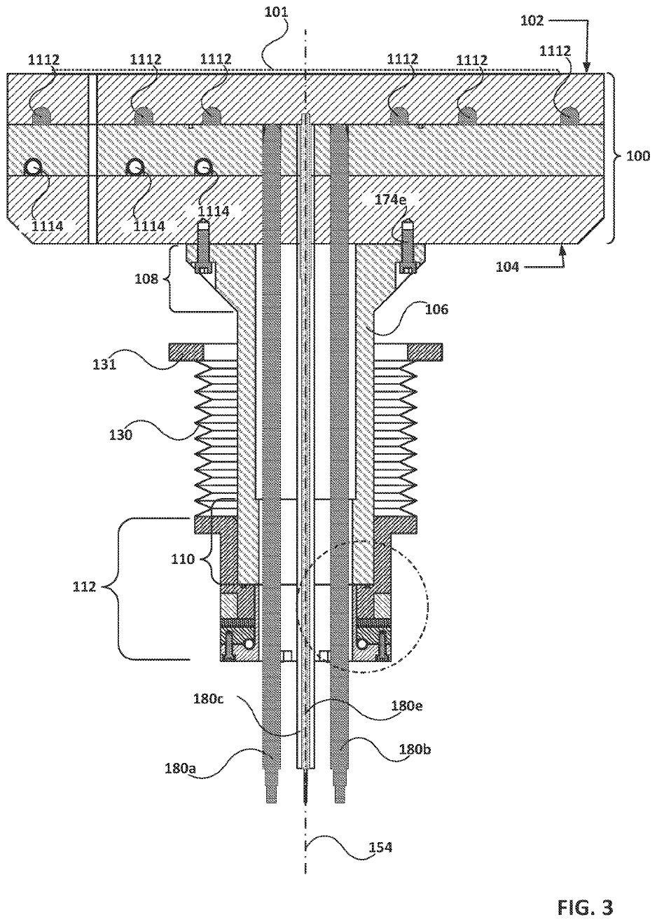

FIG. 3 depicts a cross-sectional view of the apparatus of FIG. 1. As can be seen in FIG. 3, the first side 102 of the pedestal 100 may be used to support a wafer 101 (shown in dotted outline) during semiconductor processing operations. The pedestal 100, in this example, has both active heating and cooling features. For example, the pedestal 100 may include one or more resistive heating elements 1112 that may be caused to generate heat in order to heat the first side 102 of the pedestal 100. The pedestal 100 may also include one or more pedestal cooling passages 1114 through which a coolant may be flowed in order to cause the temperature of the pedestal 100 to be lowered. The pedestal cooling passage(s) 1114 may, it will be understood, follow a path or paths that traverse across the cross-sectional area of the pedestal 100 in a more or less distributed fashion (the view of FIG. 3 is taken in a section plane that happens to bisect a region on the right where there are no portions of the pedestal cooling passage(s) present). The stem 106 is hollow to allow elongate structures 180, e.g., first electrical conductor (or cable) 180a and second electrical conductor (or cable) 180b for providing electrical power to the resistive heating elements 1112, pedestal coolant supply and return passages 180c and 180d (not shown), and sensor cable 180e to extend from the second side 104 of the pedestal 100 through the second end 110 of the stem 106 (and through the support structure 112). As can be seen, the elongate structures 180 may extend generally along a center axis 154 of the pedestal 100 and/or stem 106.

As can be seen, the stem 106 has a first end 108 that is connected with the second side 104 of the pedestal 100. In this example, the stem 106 has a circular pattern of through-holes that align with threaded holes in the second side 104 of the pedestal 100. A plurality of threaded fasteners 174e may be inserted through the through-holes in the first end 108 of the stem 106 and into the threaded holes in the second side 104 of the pedestal 100, thereby clamping the first end 108 of the stem 106 to the pedestal 100. In some other implementations, the stem 106 may be welded to the second side 104 of the pedestal 100, while in yet further implementations, the stem 106 may be connected with the pedestal 100 by virtue of the stem 106 and the pedestal 100 (or a sub-portion thereof) being machined out of the same piece of material, e.g., the stem 106 is contiguous with the bottom portion of the pedestal 100.

The bellow seal 130 may, as discussed earlier, be connected with a mounting flange 131 or other similar structure at one end and may be connected with the support structure 112 at the other.

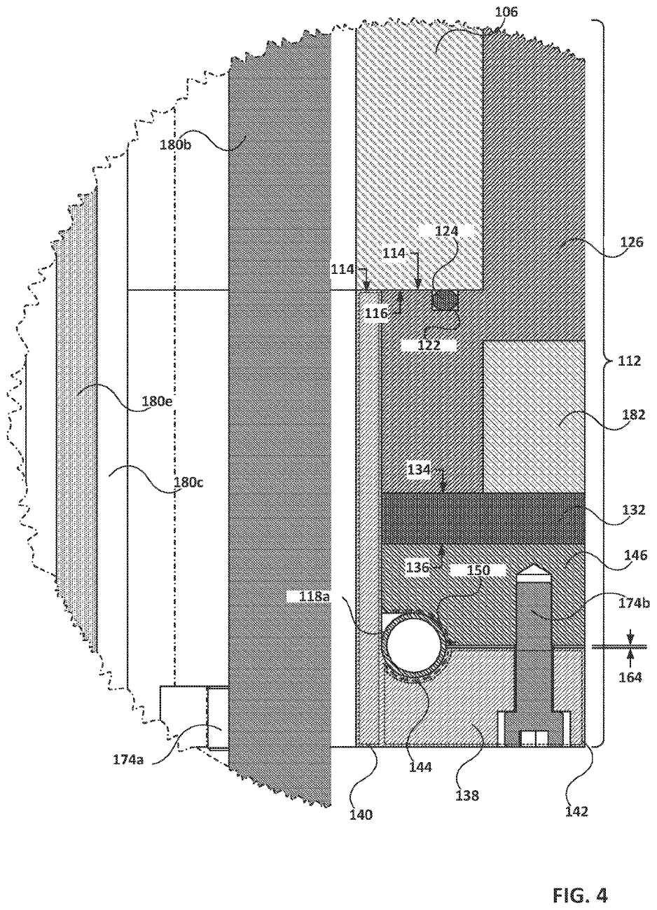

FIG. 4 depicts a detail view of the circled region of FIG. 3 and provides details on the support structure 112. As can be seen in FIG. 4, the support structure 112 includes one or more first surfaces 114 that are axially mated, e.g., along the center axis 154, with one or more second surfaces 116 of the stem, e.g., that are at or proximate to the second end 110 of the stem 106.

In this example, there are two first surfaces 114—one located on the seal collar 126 and the other located at the end of a first portion 140 of the retention collar 138. When the support structure 112 is fully assembled and mated to the second end 110 of the stem 106, both first surfaces 114 contact the second surface 116 of the stem 106. In other implementations, however, there may be more or fewer of the first surfaces 114 and/or the second surfaces 116.

In some implementations, there may be a seal 124 compressed between the one or more first surfaces 114 and the one or more second surfaces 116 to prevent gases that may be trapped between the bellow seal 130 and the stem 106 from escaping through the support structure 112 (or that may prevent atmospheric gases from leaking into the space between the bellow seal 130 and the stem 106 (and then into the processing chamber). The seal 124 may be housed in a seal groove 122 that may be formed in one or both of the one or more first surfaces and one or more second surfaces. In this example, the seal groove 122 is located in the first surface 114 that is part of the seal collar 126, but it will be readily acknowledged that such a seal groove 122 may also be located in one of the one or more second surfaces 116 instead.

Also visible in FIG. 4 is a first cooling passage segment 118a that is positioned such that the at least one first surface 114 is interposed between the first cooling passage segment 118a and the stem 106. Such an arrangement helps provide a direct thermal conduction path between the stem 106 and the first cooling passage segment 118a, e.g., without any reversals in heat flow direction. This, in turn, may increase the rate at which the first cooling passage segment 118a is able to remove heat from the stem 106.

In FIG. 4, the first cooling passage segment 118a is located between a second portion 142 of the retention collar 138 and the stem 106, e.g., the second surface(s) 116 of the stem 106. In the depicted example, the first portion 140 of the retention collar 138 abuts and is compressed against the second end 110 of the stem 106, e.g., against one of the one or more second surfaces 116. Such compression may be achieved, for example, by way of the threaded fasteners 174a, which may be inserted into through-holes in the first portion 140 of the retention collar 138 and into threaded holes in the second end of the stem 106. The first portion 140 of the retention collar 138 may thus serve as a heat conduction path from the stem 106, past the seal collar 126 and the polymeric layer 132, and to the first cooling passage segment 118a. As discussed above, the seal collar 126 may, in some instances, be made of a stainless steel alloy and may thus have relatively poor thermal conductivity. Similarly, the polymeric layer 132 will have even worse thermal conductivity than the seal collar 126. The first portion 140 of the retention collar 138 may thus provide an alternate heat conduction path from the stem 106 to the first cooling passage segment 118a.

To facilitate heat conduction via the first portion 140 of the retention collar 138, the retention collar 138 may, for example, be made of a material having a high thermal conductivity, such as copper or a copper alloy or such as aluminum or an aluminum alloy. The first cooling passage segment 118a may similarly be made of such a material. The retention collar 138 may also, for example, be equipped with a first recessed region 144 that has a matching contour to the first cooling passage segment 118a. In this example, the first cooling passage segment 118a is a round cross-section tube that has been bent into a C-shaped or arcuate shape that has an interior radius that matches or is slightly larger than the radius of the first portion 140 of the retention collar 138 (such that the first cooling passage segment 118a extends around the first portion 140 of the retention collar 138). The first recessed region 144 in this example is a channel having a generally semicircular cross-sectional profile. The semicircular cross-sectional profile has a radius that is nominally the same as the outer radius of the round cross-section tube that forms the first cooling passage segment 118a. The channel that provides the first recessed region 144 follows a path that matches that of the first cooling passage segment 118a. This allows the first cooling passage segment 118a to be positioned within, and in contact with, the first recessed region 144.

In some implementations, the load distributor 146, if used, may also have a similar recessed region, e.g., a second recessed region 150, in a face of the load distributor 146 facing towards the first cooling passage segment 118a. The second recessed region 150, for example, may have a cross-sectional shape similar to that of the first recessed region 144 and may follow a similar path, thereby allowing the first cooling passage segment 118a to also be positioned within, and in contact with, the first recessed region 144. However, it will be understood that if the first cooling passage segment 118a is provided using, for example, a tube having an asymmetric profile, e.g., a semicircular profile that transitions to a rectangular profile, then the first recessed region 144 and the second recessed region 150 may have different cross-sectional profiles but may still follow similar paths.

The polymeric layer 132 may act as a compliance element that allows the first portion 140 of the retention collar 138 to be pressed into good thermal contact with the stem while simultaneously applying a lesser compressive load to the load distributor 146, the polymeric layer 132, the support collar 182, and the portion of the seal collar 126 that is compressed between the second portion 142 of the retention collar 138 and the stem 106, e.g., the second surface(s) 116 of the stem 106. This causes the first cooling passage segment 118a to be pressed into contact with the first recessed region 144 and the second recessed region 150, thereby increasing the thermal contact area between the first cooling passage segment 118a and the retention collar 138 and the load distributor 146. It will be noted that the retention collar 138 and the load distributor 146 may be configured such that a gap 164 may exist between the surfaces of the retention collar 138 and the load distributor 146 that are closest to one another at least when the first cooling passage segment 118a is in contact with both the retention collar 138 and the load distributor 146 but in an uncompressed state. The gap 164 may be relatively small; it serves to ensure that the compressive load from the polymeric layer 132 that is directed through the load distributor 146 and then the first cooling passage segment 118a and into the retention collar 138 passes entirely or almost entirely through the first cooling passage segment 118a, thereby avoiding a scenario where the load is split between the first cooling passage segment 118a and the retention collar 138 or where all of the load or nearly all of the load passes from the load distributor 146 into the retention collar 138 with none or almost none of it passing through the first cooling passage segment 118a. In such an instance, there might be a lower amount of force pressing the first cooling passage segment 118a into contact with the first recessed region 144 and/or second recessed region 150, resulting in a thermal contact interface between the first cooling passage segment 118a and the first recessed region 144 and/or second recessed region 150 having much lower thermal conductivity than would be achieved when the gap 164 is provided.

Accordingly, the polymeric layer 132 may be sized such that when a first side 134 of the polymeric layer 132 facing towards the stem and a second side 136 of the polymeric layer 132 facing in an opposite direction are both in contact with other portions of the support structure 112 (those portions that the polymeric layer 132 would be in contact with when the support structure 112 is fully assembled) but the polymeric layer 132 is in an unloaded or uncompressed state, the first portion 140 of the retention collar 138 is not in contact with the second end 110 of the stem 106.

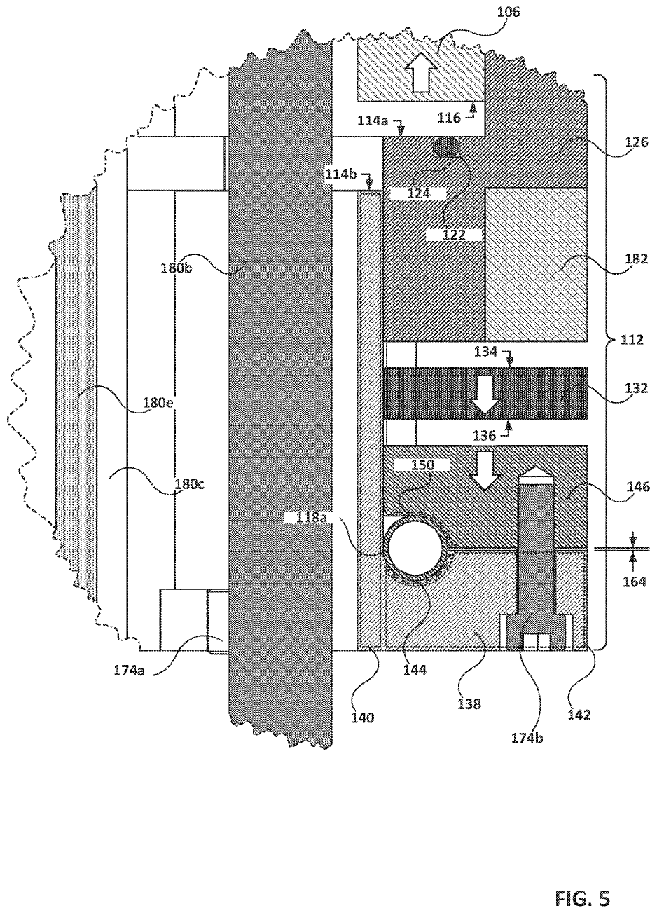

FIG. 5 shows the same cross-sectional detail view as FIG. 4, but with the stem 106 partially withdrawn from the support structure 112 and the retention collar 138 and polymeric layer 132 each partially withdrawn from the seal collar 126 by different amounts. FIG. 5 is provided simply to provide greater clarity as to the first surfaces 114a and 114b (previously simply referred to as first surfaces 114) and the second surface 116, as well as the first side 134 and the second side 136 of the polymeric layer 132.

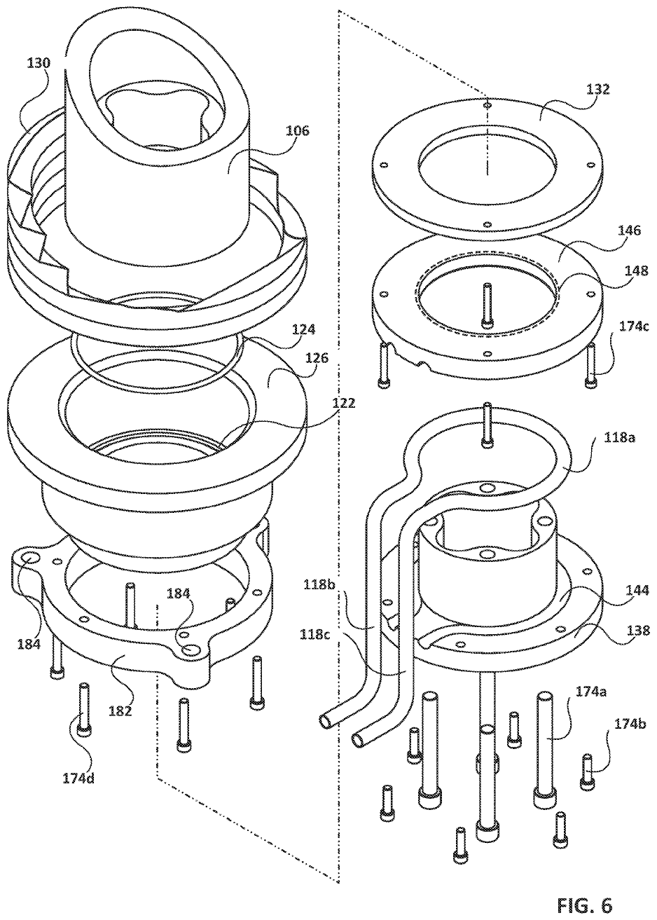

FIG. 6 depicts an exploded perspective view of the support structure 112 discussed above. Portions of the bellow seal 130 and stem 106 are also visible. The bellow seal 130 is shown as removed from the seal collar 126 although it would normally be welded or otherwise attached thereto.

In this example, the seal collar 126 may be inserted through an opening in the support collar 182, such that the support collar 182 is constrained from radial movement relative to the seal collar 126. The seal collar 126 may, for example, have a flange that extends radially outward from the portion of the seal collar 126 that extends through the support collar 182. The flange, for example, may support the seal collar 126 axially relative to the support collar 182. The support collar 182 may, as mentioned before, have a plurality of mounting features 184 that are positioned about an outer perimeter of the support collar 182. The mounting features 184 may, for example, be through-holes or threaded holes in some implementations and may be used to receive or mount support features, such as rods, columns, or other structural supports that may support the support collar 182 relative to some other structure, e.g., a movable base that may be used to move the pedestal 100 up and down vertically. In this implementation, the support collar 182 is bolted to the seal collar 126 using a plurality of threaded fasteners 174d, thereby joining the support collar 182 and the seal collar 126 into an assembly.

The polymeric layer 132 and the load distributor 146, in this example, may be attached to the support collar 182, e.g., via threaded fasteners 174c. Such threaded fasteners 174c may, for example, be shoulder screws that may retain the load distributor 146 in position relative to the seal collar 126 and the support collar 182 but which may bottom out against the support collar 182 and thereby exert only a limited amount of compressive force on the polymeric layer 132.

The second end 110 of the stem 106 may, during assembly, be inserted into the seal collar 126 after the seal 124 is installed in the seal groove 122. The cooling passage 118, e.g., the first cooling passage segment 118a, may be positioned within, and in contact with, the second recessed region 150 (which may extend around an opening 148). The first portion 140 of the retention collar 138 may then be inserted through the first cooling passage segment 118a and the opening 148 of the load distributor 146 (and a similar opening in the polymeric layer 132 and the seal collar 126) so as to butt up against the second end 110 of the stem 106, thereby causing the first cooling passage segment 118a to be positioned in the first recessed region 144. The retention collar 138 may, for example, be connected with the load distributor 146 via a plurality of threaded fasteners 174b that are inserted through holes in the retention collar 138 and into threaded holes in the load distributor 146. Such fasteners 174b may serve to retain the retention collar 138 in place relative to the load distributor 146 and may apply some compression to the first cooling path segment 118a. However, the retention collar 138 may also be retained in placed by threaded fasteners 174a, which may be inserted through through-holes in the first portion 140 of the retention collar 138 and into threaded holes in the second end 110 of the stem 106.

It will be noted that the first cooling passage segment 118a may, for example, be fluidically connected with, and fluidically interposed between, a second cooling passage segment 118b and a third cooling passage segment 118c. For example, the cooling passage may be a length of tubing, e.g., copper tubing, that has been bent into a particular shape, e.g., including the shape of the first cooling passage segment 118a. The second cooling passage segment 118b and the third cooling passage segment 118c may, for example, extend in directions perpendicular to the plane in which the path that the first cooling passage segment 118a follows lies. Portions of the cooling passage, e.g., the ends of the second cooling passage segment 118b and the third cooling passage segment 118c that are not connected with the first cooling passage segment 118a, may, in some implementations, be clamped or otherwise fixed in space relative to the support structure 11.

It will be noted that the retention collar 138 may be removed from the support structure 112, e.g., by removing the threaded fasteners 174a and 174b, while leaving the first cooling passage segment 118a, as well as the second cooling passage segment 118b and the third cooling passage segment 118c in place, e.g., without requiring that the second cooling passage segment 118b and the third cooling passage segment 118c be moved relative to the first portion. Such a design allows for the stem 106 (and the pedestal 100 that it supports) to be removed from the support structure 112 without requiring that the cooling passage 118 be breached in any way, e.g., without requiring that the cooling passage 118 be unsealed or removed. This avoids the need, for example, to drain the cooling system of coolant prior to removing the stem 106, thereby reducing the amount of time and effort required to remove and re-install the pedestal 100 (or replace it with a new pedestal 100).

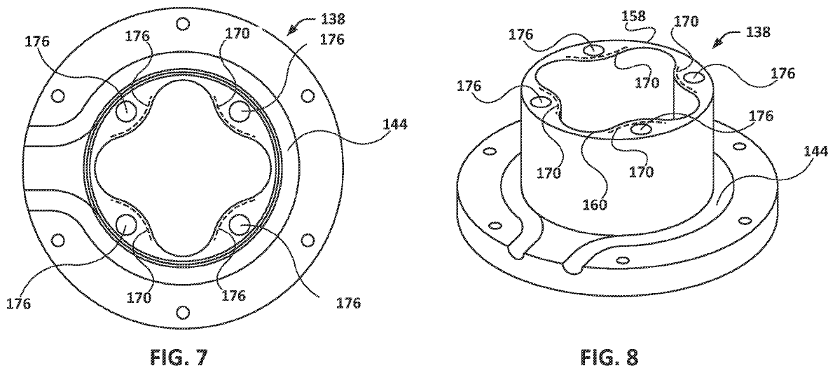

FIGS. 7 and 8 depict top and perspective views of the example retention collar 138 shown in earlier Figures. The first recessed region 144 is visible in FIGS. 7 and 8. As can be seen, the first portion 140 of the retention collar 138 may have an outer surface that is cylindrical in nature, similar to that of the stem 106. However, the interior edge 160 of the first portion 140 of the retention collar 138 may, in some cases, have a plurality of lobes 170 that extend radially inward from an exterior edge 158. Such lobes 170 may, for example, accommodate through-holes 176 that the threaded fasteners 174a may be inserted through. The stem 106 may, in some cases, similarly have lobes (not called out, but visible) that match, e.g., that are similar in dimension and shape and rotationally aligned with the lobes 170 of the retention collar 138. The lobes of the retention collar 138 may similarly accommodate threaded holes (not shown) into which the threaded fasteners 174a may be threaded. For clarity, it will be understood that the lobes 170 of the retention collar 138 and the lobes of the stem (if the stem has lobes) may, in some cases be referred to as “first lobes” and “second lobes” (or vice-versa, depending on the context). In some cases, the lobes of the retention collar 138 may terminate at or provide, e.g., terminate coplanar with, the first surface(s) 114 and the lobes of the stem 106 may terminate at or provide, e.g., terminate coplanar with, the second surface(s) 116.

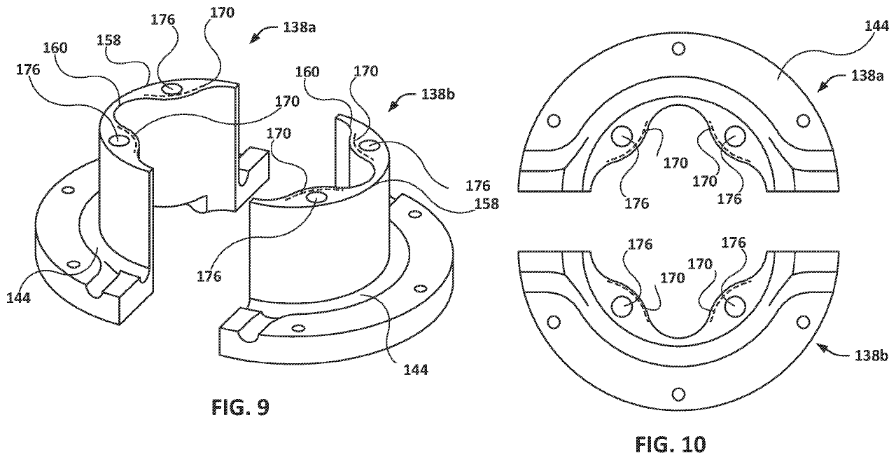

FIGS. 9 and 10 depict perspective and top views of an alternate retention collar in which the retention collar is a split or two-part retention collar. As shown, the retention collar features two halves 138a and 138b. The other features shown in FIGS. 9 and 10, however, are the same as in the retention collar 138 of FIGS. 7 and 8 and are not described again here. Splitting the retention collar 138 into two halves 138a and 138b, allows the retention collar 138 to be removed from the support structure 112 (or installed into the support structure 112) without needing to disconnect the cooling supply passage, the cooling return passage, or the first or second electrical conductors (if present). It will be noted that the first recessed region 144 that is provided in each of the halves 138a and 138b is symmetric, e.g., having portions thereof that are mirrored about a center plane that is perpendicular to the split plane that divides the two halves 138a and 138b from one another. Such a construction allows the two halves 138a and 138b to be interchangeable, thereby reducing the number of potentially different unique parts and also making it more difficult to assemble incorrectly. In other implementations, however, the two halves 138a and 138b may not be symmetric, e.g., each may have its own unique component design.

The use of the first lobes 170 within the first portion 140 of the retention collar 138 may allow the retention collar 138 to have an increased thickness (and thus a larger thermally conductive heat transfer path) in the region with the first lobes 170 while providing space in between the first lobes 170 to allow various elongate structures 180, e.g., 180a-d, to be routed through the retention collar 138. For example, each of the elongate structures 180a-d may have a portion that is positioned in between two adjacent first lobes 170.

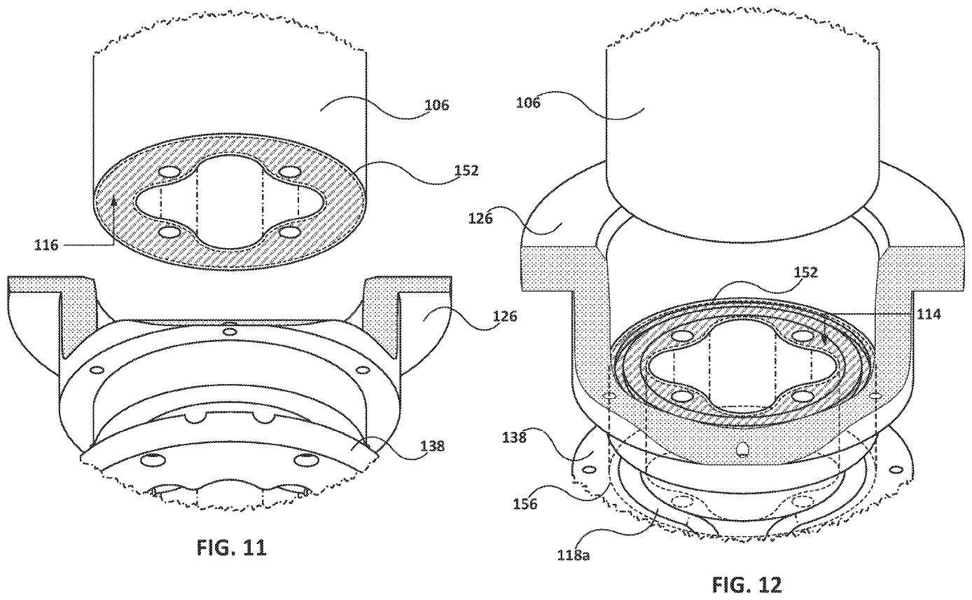

FIGS. 11 and 12 depict perspective cutaway exploded views of the support structure 112 (with only the seal collar 126 and the retention collar 138 shown) and the second end 110 of the stem 106. FIGS. 11 and 12 are provided primarily to help illustrate a contact region 152 where the first surface(s) 114 of the support structure 112 and the second surface(s) 116 of the stem 106 overlap each other when viewed along the center axis 154. The contact region 152 is indicated by the diagonal-shaded hatching in FIGS. 11 and 12 and defines a cross-section of a reference volume 156 that extends along the center axis 154. In some implementations, the first cooling passage segment 118a may lie at least partially within (or mostly within) the reference volume 156. Such placement may, for example, cause the first cooling passage segment 118a to be positioned beneath the contact region 152, thereby reducing the distance that heat must travel in order to reach the first cooling passage segment 118a from the contact region 152.

It will be appreciated that the above principles and concepts may be implemented in a variety of ways. In particular, various elements that are shown as discrete parts or components in the above-discussed examples may be combined in other implementations, or such parts or components may be arranged differently.

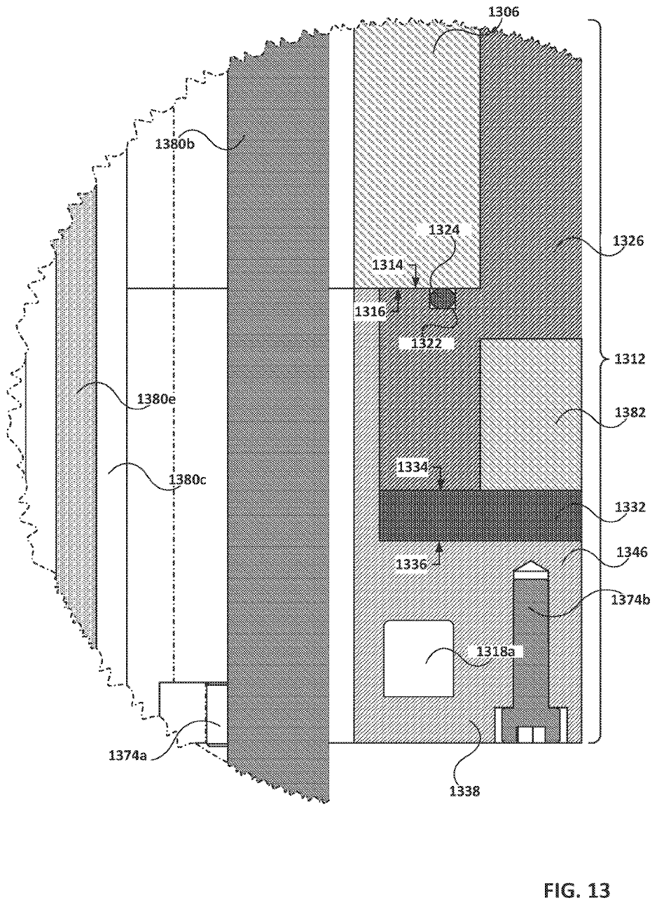

FIG. 13 depicts a cross-section similar to that of FIG. 4. The elements of FIG. 13 that are called out with callouts having the same last two digits as elements in FIG. 4 may be assumed to be generally similar in function and structure unless indicated otherwise, either explicitly or implicitly. The implementation of FIG. 13 is generally similar to that of FIG. 4, except that in the depicted implementation there is no load distributor 1346 and the first cooling passage segment 1318a is not provided by a separate piece of tubing that is clamped in between the retention collar 1338 and the load distributor 1346. Instead, the retention collar 1338 includes within it the first cooling passage segment 1318a, e.g., a channel or passage that follows a C-shaped path and is provided within the body of the retention collar 1338. The channel or passage may be connected with a coolant inlet at one end and a coolant outlet at the other. In the case where the first cooling passage segment 1318a is provided by way of a channel in the retention collar 1338, the channel may, in some implementations, be capped by a plate that is welded, bonded, or otherwise sealed to the remainder of the retention collar 1338. If the retention collar 1338 is, for example, manufactured using additive manufacturing, e.g., laser metal sintering, the first cooling passage segment may simply be printed in place during the manufacturing process.

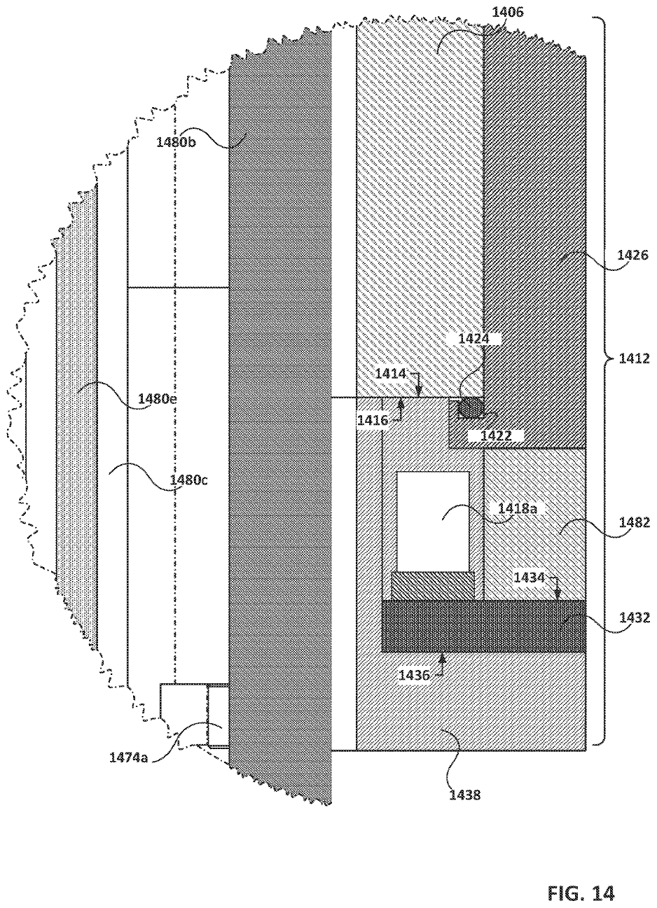

FIG. 14 depicts another alternative in which the first cooling passage segment 1418a is formed in the retention collar 1438 but is positioned above (or overlapping with) the polymeric layer 1432. The elements of FIG. 14 that are called out with callouts having the same last two digits as elements in FIG. 4 may be assumed to be generally similar in function and structure unless indicated otherwise, either explicitly or implicitly. Such an approach may allow the first cooling passage segment 1418a to be positioned very close to the first surface(s) and second surface(s), thereby dramatically shortening the conductive heat transfer path from the stem 1406 to the first cooling passage segment 1418a.

The examples of FIGS. 13 and 14 may provide similar improved cooling performance as compared with the earlier examples discussed herein but may also be more difficult to service and install since the first cooling passage segment 118a is located within the retention collar 138. Removal of the retention collar 138, e.g., to remove the stem 106, may thus require that the coolant in the first cooling passage segment 118a be removed.

The pedestals 100, stems 106, and support structures 112 discussed herein may, for example, be installed in semiconductor processing chambers and used in semiconductor processing operations in which the wafers being processed are subjected to relatively high temperatures, e.g., 600° C., while allowing the interface where the stem 106 mates with the support structure 112 (where the seal 124 is located) to be maintained at a much lower temperature, e.g., below 250° C. For example, implementations such as that shown in FIG. 1 may be capable of, when the pedestal 100 is maintained at a temperature of 600°, maintaining the temperature of the second end 110 of the stem 106 at a temperature of ~235° C. when the retention collar 138 is made of aluminum alloy and potentially at a temperature of ~215° when the retention collar 138 is made of a copper alloy or pure copper. The use of high-thermal-conductivity materials, such as copper or alloys thereof, for the retention collar 138 and the first cooling passage segment 118a provides a much more thermally conductive heat transfer path than can be provided with stainless steel or other materials that are commonly used in semiconductor processing equipment.

For example, the use of copper is often avoided due to copper's reactivity with many species of semiconductor processing gas, which may result in undesirable particulate generation should copper surfaces be exposed to such gases. Such particulates may, for example, end up depositing on a wafer being processed, which may render the wafer unusable.

In the design of FIG. 3, for example, the retention collar 138 and the first cooling passage segment 118a are both located outside of the seal boundary that encloses the interior of the semiconductor processing chamber where the pedestal 100 would reside, thereby protecting the retention collar 138 and the first cooling passage segment 118a from potential exposure to semiconductor processing gases and also preventing any particulates that might be shed from the retention collar 138 and the first cooling passage segment 118a from reaching the interior of the semiconductor processing chamber. This allows the use of copper or copper alloys in the retention collar 138 and the first cooling passage segment 118a without the risk of copper being exposed to the process gases within the semiconductor processing chamber.

Generally speaking, the stem 106 may be made of aluminum, which may be chemically compatible with the process gases to which the stem 106 and the pedestal 100 may be exposed and which may also have a relatively high thermal conductivity (although significantly lower than that of copper, e.g., approximately half that of copper). The metal bellow seal 130, however, is typically made of stainless steel due to the need for it to be chemically resistant and to have high resistance to fatigue failure. As discussed earlier, the metal bellow seal 130 is typically welded to another component, the seal collar 126, that may also be made of stainless steel. The seal collar 126 may serve as the seat against which the stem 106 butts against in order to seal against the seal 124.

The use of copper in the retention collar 138 provides a high-thermal-conductivity pathway from the stem 106 to the first cooling passage segment 118a that exists in parallel with a much lower thermal conductivity pathway from the stem to the first cooling passage segment 118a that is provided by way of the seal collar 126 (likely made of stainless steel) and polymeric layer 132 (made of a polymeric material). Such a configuration causes the majority of the heat from the stem 106 to flow through the retention collar 138 to the first cooling passage segment 118a, thereby significantly reducing the amount of heat that flows through the seal collar 126 and the polymeric layer 132. This reduces the potential for heat building up in the seal collar 126 and the polymeric layer 132, which may damage the polymeric layer 132 and/or the seal 124.

Moreover, as mentioned earlier, positioning the first cooling passage segment 118a at least partially within the reference volume 156 may further increase the cooling efficiency of such a pedestal assembly by moving the first cooling passage segment 118a closer to the end of the retention collar 138 that interfaces with the stem 106, thereby reducing the heat conduction path length from the stem 106 to the first cooling passage segment 118a.

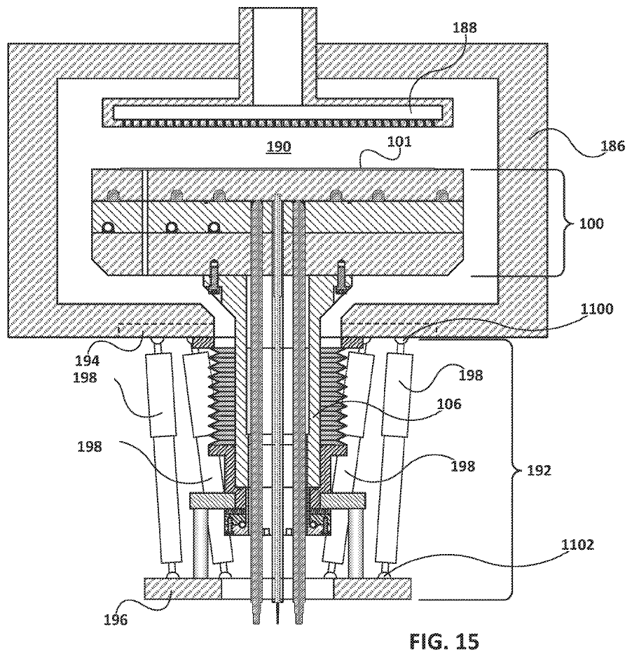

FIG. 15 depicts one example of a semiconductor processing system in which such processes may be performed. As can be seen, the pedestal 100 and the first end of the stem 106 are located within an interior volume 190 of a processing chamber 186. The second end of the stem 106 is, however, located outside of the interior volume 190 of the processing chamber 186. A showerhead 188 may be positioned within the interior volume 190 and used to distribute one or more processing gases during wafer processing operations to a wafer 101 that may be supported by the pedestal 100.

The second end of the stem 106 may be connected with a support structure 112 that is fixedly coupled with a movable base 196 of a hexapod mechanism 192. The hexapod mechanism 192 may also include a stationary base 194 and a plurality, e.g., six, linear actuators 198 that have first ends 1100 connected with the stationary base 194 and second ends 1102 connected with the movable base 196/. The linear actuators 198 may be arranged so as to form a statically determinate kinematic system that is, through controlled actuation of the linear actuators 198, able to cause the movable base 196 to be movable vertically, horizontally, and rotationally about both horizontal and vertical axes.

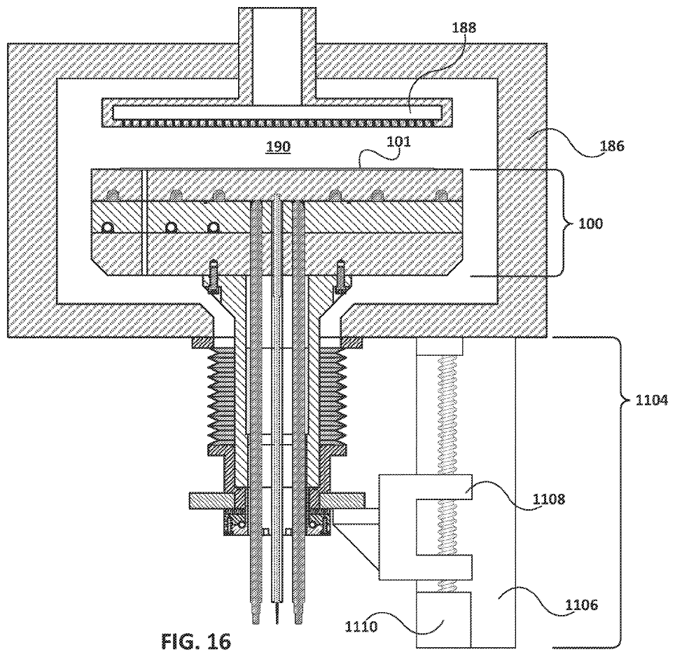

FIG. 16 depicts an alternate example semiconductor processing system that is similar to that depicted in FIG. 15 except that the hexapod mechanism 192 has been replaced with a single-axis vertical lift mechanism 1104. The vertical lift mechanism 1104 may, for example, have a base portion 1106 that may generally be fixed with respect to the processing chamber 186 and a movable portion 1108 that may be movably coupled with the base portion 1106. For example, the base portion 1106 may include within it an actuator 1110 that may be used to drive a linear screw that is threaded through a nut or other threaded interface in the movable portion 1108. By actuating the actuator 1110, the linear screw may be caused to rotate, thereby causing the movable portion 1108 of the vertical lift mechanism to move up and down vertically.

It will be understood that while the stem designs discussed above are structured so as to provide for conductive heat transfer paths that have high thermal conductance, thereby allowing a pedestal to be kept at a significantly elevated temperature, e.g., 600° C. to 700° C., while allowing the based of the stem supporting the pedestal to be kept at a much lower temperature, e.g., 250° C., such designs may, in some instances, be implemented slightly differently in order to deliberately provide for lower thermal conductance. Since the retention collar acts as the primary conductive heat transfer path from the stem to the cooling passage segment(s), it is relatively easy to re-tune such a pedestal to have a lower thermal conductance, e.g., by using a retention collar that is made of a material having a lower thermal conductivity. Such implementations may be advantageous in semiconductor processing tools in which it may be desirable to have a slower rate of heat transfer out of the pedestal. For example, in some semiconductor processes, heat may be generated within the pedestal through the process conditions themselves, e.g., due to RF energy absorbed by the pedestal and/or due to chemical reactions or plasmas that occur within the semiconductor processing chamber, without the need for a separate heater system. In some such instances, it may still be desirable to maintain the pedestal at an elevated temperature (although likely lower than the 600° C. to 700° C. examples discussed above). Such process-generated heat may be sufficient to heat the pedestal to the desired target temperature. However, if the stem has a high thermal conductance, the rate of heat transfer out of the pedestal may be high enough that it is difficult to maintain the desired target temperature. In such instances, the retention collar may be used, in effect, as a thermal choke point—by making the retention collar out of a material with lower thermal conductivity, e.g., such as stainless steel, brass, nickel, or bronze alloys or glass-filled or metal-filled composites or plastics, polyamides, and/or by having part of the first portion of the retention collar be provided by one or more layers of such material, the thermal conductance of the retention collar may, for example, be de-tuned so as to have a deliberately lower thermal conductance than it would otherwise have if made of a material such as solid copper or aluminum. Additionally, the radial thickness of the first portion of the retention collar and/or the length of the first portion of the retention collar may be thinned and/or lengthened, respectively, to reduce the heat transfer through the retention collar to provide additional reductions in thermal conductance through the retention collar. Thus, it will be recognized that the structures discussed herein, while designed to provide a conductive heat transfer path that is highly conductive, may also be reconfigured to provide conductive heat transfer paths that have much lower thermal conductance, depending on the thermal needs of a particular semiconductor process. Such approaches may, for example, provide an entirely passive option for reducing the heat flow out of the pedestal as compared to, for example, modifying the rate of coolant flow and/or changing the temperature of the coolant.

Semiconductor processing tools incorporating the pedestals, stems, and support structures discussed herein may be controlled with a controller that may be programmed to control any of the processes disclosed herein, such as processes for controlling the pedestal, as well as other processes or parameters not discussed herein, such as the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a chamber and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application-specific integrated circuits (ASICs), and/or one or more microprocessors or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some examples, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example pedestals according to the present disclosure may be mounted in or part of semiconductor processing tools with a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The term “operatively connected” is to be understood to refer to a state in which two components and/or systems are connected, either directly or indirectly, such that, for example, at least one component or system can control the other. For example, a controller may be described as being operatively connected with a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely cannot supply such power directly to the resistive heating unit due to the currents involved, but it will be understood that the controller is nonetheless operatively connected with the resistive heating unit.

It is understood that the examples and implementations described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

1. A system comprising:
a pedestal having a first side configured to support a semiconductor wafer during semiconductor processing operations and a second side opposite the first side;
a stem having a first end connected with the pedestal and a second end located farther from the second side than the first end of the stem;
a support structure connected with the second end of the stem, the support structure having at least one first surface that is axially mated with a second surface located at or proximate to the second end of the stem; and
a first cooling passage segment positioned such that the at least one first surface is interposed between the first cooling passage segment and the stem.

2. The system of claim 1, wherein:
the support structure comprises a seal collar connected with a bellow seal,
the bellow seal encircles at least part of the stem, and
the bellow seal is made of metal.

3. The system of claim 2, wherein the support structure further comprises:
a polymeric layer interposed between at least a portion of the seal collar and the first cooling passage segment; and
a retention collar having a first portion abutting the second end of the stem and a second portion connected with the first portion, wherein the first cooling passage segment is positioned between the second portion of the retention collar and the second surface of the stem.

4. The system of claim 3, wherein:
the first cooling passage segment is a tube that extends around the first portion of the retention collar,
the support structure is configured such that the first portion of the retention collar is compressed against the second end of the stem, and
at least a portion of the polymeric layer adjacent to the seal collar is in a state of compression.

5. The system of claim 4, wherein the polymeric layer:
has a first side facing the stem and a second side facing an opposite direction from the first side, and
is sized such that when the polymeric layer is in an uncompressed state and the first side of the polymeric layer and the second side of the polymeric layer are both in contact with other portions of the support structure, the first portion of the retention collar is not in contact with the second end of the stem.

6. The system of claim 4, wherein:
the at least one first surface of the support structure and the second surface of the stem define a contact region where the at least one first surface and the second surface overlap one another when viewed along a center axis of the stem extending between the first end of the stem and the second end of the stem, and
the first cooling passage segment lies at least partially within a reference volume bounded by interior and exterior edges of the contact region and extending along the center axis of the stem.

7. The system of claim 4, wherein:
the tube follows a path around the first portion of the retention collar,
the second portion of the retention collar has a first recessed region extending around the first portion of the retention collar, and
the tube is positioned within, and in contact with, the first recessed region.

8. The system of claim 7, wherein the support structure further comprises a load distributor that is at least partially interposed between:
the first cooling passage segment and the polymeric layer, and
the second portion of the retention collar and the polymeric layer, and wherein the first cooling passage segment is interposed between at least a portion of the second portion of the retention collar and a portion of the load distributor.

9. The system of claim 8, wherein:
the load distributor has an opening through which the first portion of the retention collar extends,
the load distributor has a second recessed region extending around the opening, and
the tube is positioned within, and in contact with, the second recessed region.

10. The system of claim 8, wherein a gap exists between the load distributor and the second portion of the retention collar when the first cooling passage segment is at least touching, but not compressed between, both the load distributor and the retention collar.

11. The system of claim 3, wherein the second end of the stem has a first interior perimeter having a plurality of first lobes extending radially inward from outermost portions of the first interior perimeter.

12. The system of claim 11, wherein:
the retention collar has a second interior perimeter having a plurality of second lobes extending radially inward from outermost portions of the second interior perimeter, and
the first lobes and the second lobes are rotationally aligned with each other.

13. The system of claim 12, wherein the first lobes terminate at the second surface and the second lobes terminate coplanar with the at least one first surface.

14. The system of claim 11, further comprising a plurality of elongate structures extending from the second side of the pedestal and through the stem, wherein each elongate structure has a portion that is positioned in between two of the first lobes that are adjacent to one another.

15. The system of claim 7, further comprising a second cooling passage segment and a third cooling passage segment, wherein:
the first cooling passage segment is fluidically interposed between the second cooling passage segment and the third cooling passage segment,
the first cooling passage segment, the second cooling passage segment, and the third cooling passage segment are connected together,
the second cooling passage segment and the third cooling passage segment each have a respective portion that is fixed in space relative to a first portion of the support structure, and
the retention collar is connected with one or more other components of the support structure such that the retention collar is removable from a remainder of the support structure without requiring that the respective portions of the second cooling passage segment and the third cooling passage segment moved relative to the first portion of the support structure.

16. The system of claim 15, wherein the retention collar comprises two halves.

17. The system of claim 3, wherein the support structure further includes a support collar that is interposed between a portion of the seal collar and a portion of the retention collar, the support collar having a plurality of mounting features positioned about an outer perimeter thereof.

18. The system of claim 1, further comprising:
a processing chamber; and
a showerhead, wherein:
the pedestal is located within an interior volume of the processing chamber, and
the first end of the stem is located within the interior volume of the processing chamber and the second end of the stem is located outside of the processing chamber.

19. The system of claim 18, further comprising a hexapod mechanism with a stationary base, a movable base, and six linear actuators, wherein:
the support structure is mounted to the movable base,
the stationary base is mounted to the processing chamber,
a first end of each linear actuator is connected with the stationary base, and
a second end of each linear actuator is connected with the movable base.

20. The system of claim 18, further comprising a vertical lift mechanism having a base portion and a movable portion, wherein the support structure is fixed in space with respect to the movable portion and the vertical lift mechanism includes one or more actuators configured to cause the movable portion to move relative to the base portion responsive to one or more input signals.
